(19) United States
(12) Patent Application Publication
(10) Pub. No.: US 2025/0212512 A1
(43) Pub. Date: Jun. 26, 2025

(54) DISPLAY PANEL

(71) Applicant: Wuhan China Star Optoelectronics Technology Co., Ltd., Wuhan, Hubei (CN)

(72) Inventors: Zhifu LI, Wuhan, Hubei (CN); Guanghui LIU, Wuhan, Hubei (CN); Fei AI, Wuhan, Hubei (CN); Dewei SONG, Wuhan, Hubei (CN); Zhuang LI, Wuhan, Hubei (CN)

(73) Assignee: Wuhan China Star Optoelectronics Technology Co., Ltd., Wuhan, Hubei (CN)

(21) Appl. No.: 18/851,809

(22) PCT Filed: Jun. 29, 2023
(86) PCT No.: PCT/CN2023/104277

§ 371 Date: Sep. 27, 2024

(30) Foreign Application Priority Data
Oct. 12, 2022 (CN) 202211248377.X

(51) Int. Cl. H10D 86/40; H10D 86/60

(52) U.S. Cl. CPC H10D 86/441; H10D 86/60

(57) ABSTRACT

A display panel is provided, which includes a substrate, multiple ohmic contact layers, multiple insulating layers, a semiconductor layer, a gate, and a source and drain layer. At least one insulating layer is disposed between adjacent ohmic contact layers. The semiconductor layer is disposed at least on first sidewalls of the multiple ohmic contact layers. The semiconductor layer includes multiple active parts that are in contact with the first sidewalls. The gate is disposed on a side of the semiconductor layer away from the substrate, and the source and drain layer is disposed on a side of the gate away from the substrate and is electrically connected to the corresponding ohmic contact layer.

### TECHNICAL FIELD

The present invention relates to display technology, particularly to a display panel.

### BACKGROUND

Integrating circuits such as pixel driving circuits, gate driving circuits, multiplexer circuits, source driving circuits, and timing controllers on glass substrates (System on Glass, SOG) can greatly improve integration of display panels, reduce dependence on integrated circuit chips, thereby reducing costs. Achieving SOG requires increasing integration of thin-film transistors in existing display panels, maximum operating frequency, and current density, all of which require thin-film transistors to have shorter channel lengths, higher mobility, and smaller sizes.

However, an architecture of thin-film transistors in existing display panels cannot further reduce the channel length, volume, and footprint of the thin-film transistors. Therefore, the architecture of thin-film transistors in existing display panels urgently needs improvement.

### SUMMARY

The embodiments of the present invention provide a display panel to address the technical problem of the large footprint of thin-film transistors in existing display panels.

The embodiment of the present invention provides a display panel, including:
a substrate;
multiple ohmic contact layers, stacked on the substrate;
multiple insulating layers, with at least one insulating layer of the insulating layers between two adjacent ones of the ohmic contact layers;
a semiconductor layer, disposed on at least first sidewalls of the ohmic contact layers that are on one same side, wherein the semiconductor layer includes multiple spaced active parts each in contact and connected with the first sidewalls of two of the ohmic contact layers;
a gate, disposed on a side of the semiconductor layer away from the substrate; and
a source and drain layer, disposed on a side of the gate away from the substrate, and the source and drain layer being electrically connected to a corresponding one of the ohmic contact layers.

In some embodiments of the present invention, the semiconductor layer includes multiple oxidation insulating parts, each oxidation insulating part is located between two adjacent ones of the active parts.

In some embodiments of the present invention, the active parts and the oxidation insulating parts form a continuous pattern.

In some embodiments of the present invention, an orthographic projection of the oxidation insulating part on the first sidewalls of the ohmic contact layers is located between the two adjacent ohmic contact layers.

In some embodiments of the present invention, a material of the oxidation insulating parts includes silicon oxide, and a material of the active parts comprises polycrystalline silicon.

In some embodiments of the present invention, the semiconductor layer includes a hollow part, which is located between two adjacent ones of the active parts.

In some embodiments of the present invention, the display panel includes a first ohmic contact layer, a first insulating layer, a second ohmic contact layer, a second insulating layer, a third ohmic contact layer, a third insulating layer, and a fourth ohmic contact layer, sequentially stacked on the substrate.

In some embodiments of the present invention, the semiconductor layer includes a first active part and a second active part, the first active part is in contact with the first ohmic contact layer and the second ohmic contact layer, and the second active part is in contact with the third ohmic contact layer and the fourth ohmic contact layer.

In some embodiments of the present invention, the source and drain layer includes a first source, a first drain, a second source, and a second drain, disposed on a side of the gate away from the substrate, one of the first source and the first drain is electrically connected to the first ohmic contact layer, the other of the first source and the first drain is electrically connected to the second ohmic contact layer, one of the second source and the second drain is electrically connected to the third ohmic contact layer, and the other of the second source and the second drain is electrically connected to the fourth ohmic contact layer.

In some embodiments of the present invention, orthographic projections of the first source and the first drain on the substrate are located on a side of an orthographic projection of the gate on the substrate, and the second source and the second drain are located on an opposite side of the orthographic projection of the gate on the substrate.

In some embodiments of the present invention, the first ohmic contact layer includes a first protrusion, an orthographic projection of the first protrusion on the substrate does not overlap with orthographic projections of the second, third, and fourth ohmic contact layers on the substrate, and the first protrusion is electrically connected to one of the first source and the first drain; the second ohmic contact layer includes a second protrusion, an orthographic projection of the second protrusion on the substrate does not overlap with the orthographic projections of the third and fourth ohmic contact layers on the substrate, and the second protrusion is electrically connected to the other of the first source and the first drain; the third ohmic contact layer includes a third protrusion, an orthographic projection of the third protrusion on the substrate does not overlap with the orthographic projection of the fourth ohmic contact layer on the substrate, and the third protrusion is electrically connected to one of the second source and the second drain.

In some embodiments of the present invention, the second insulating layer includes a via, and the third ohmic contact layer is electrically connected to the second ohmic contact layer through the via.

In some embodiments of the present invention, the source and drain layer includes a first source and a first drain diposed on a side of the gate away from the substrate, one of the first source and the first drain is electrically connected to the first ohmic contact layer, and the other of the first source and the first drain is electrically connected to the fourth ohmic contact layer.

In some embodiments of the present invention, an orthographic projection of the first source on the substrate is located on a side of an orthographic projection of the gate on the substrate, and an orthographic projection of the first drain on the substrate is located on the other side of the orthographic projection of the gate on the substrate.

In some embodiments of the present invention, the first ohmic contact layer includes a first protrusion, an orthographic projection of the first protrusion on the substrate does not overlap with orthographic projections of the second, third, and fourth ohmic contact layers on the substrate, and the first protrusion is electrically connected to one of the first source and the first drain.

In some embodiments of the present invention, a spacing between the first active part and the second active part is greater than zero and less than H1, where H1 is a sum of widths of the first sidewall of the second ohmic contact layer and a second sidewall of the second insulating layer and the first sidewall of the third ohmic contact layer.

In some embodiments of the present invention, the semiconductor layer further includes a horizontal part, which is in contact and connected with one of the active parts and is disposed on a surface of the substrate.

In some embodiments of the present invention, the horizontal part is inclined with respect to the active part, and an angle between the horizontal part and the active part is 90°˜135°.

In some embodiments of the present invention, a material of the horizontal part includes amorphous silicon material.

In some embodiments of the present invention, the substrate includes a base substrate, a buffer layer disposed on a side of the base substrate close to the ohmic contact layers, and a light-shielding layer located between the base substrate and the buffer layer, an orthographic projection of the light-shielding layer on the base substrate covers orthographic projections of the various active parts of the semiconductor layer on the base substrate.

### Beneficial Effects

The display panel provided by the embodiment of the present invention includes a substrate, multiple ohmic contact layers, multiple insulating layers, a semiconductor layer, a gate, and a source and drain layer, where at least one layer of insulating layers is disposed between adjacent ohmic contact layers, the semiconductor layer is disposed on at least the first sidewalls of the ohmic contact layers on same side, the semiconductor layer includes multiple spaced active parts, the active parts are in contact with the first sidewalls of the two ohmic contact layers, the gate is disposed on a side of the semiconductor layer away from the substrate, and the source and drain layer is disposed on a side of the gate away from the substrate, and is electrically connected to the corresponding ohmic contact layer. By stacking multiple ohmic contact layers and setting the semiconductor layer on the sidewalls of the ohmic contact layers, not only a length of the thin-film transistor is reduced, and an on-state current is increased, but also multiple thin-film transistors are stacked in a thickness direction of the display panel, reducing a volume of the thin-film transistors, reducing a footprint of the thin-film transistors, and is conducive to improving an integration of the device.

### BRIEF DESCRIPTION OF THE DRAWINGS

FIG. 1 is a structural plan view of the thin-film transistor provided by an embodiment of the present invention;

FIG. 2 is a cross-sectional view along the B-B direction of FIG. 1;

FIG. 3 is a cross-sectional view along the A-A direction of FIG. 1;

FIG. 4 is a diagram showing the stacked layers of the thin-film transistor provided by another embodiment of the invention;

FIG. 5 is a structural plan view of the thin-film transistor provided by another embodiment of the invention;

FIG. 6 is a cross-sectional view along the B-B direction of FIG. 5;

FIG. 7 is a cross-sectional view along the A-A direction of FIG. 5;

FIGS. 8a to 8i are structural diagrams showing the preparation process of the display panel provided by embodiments of the invention.

### DETAILED DESCRIPTION

The following will combine the drawings of the embodiment of the application to clearly and completely describe the technical solution of the embodiment of the application. Obviously, the described embodiment is only a part of the embodiments of the application, not all of the embodiments. All other embodiments obtained by those skilled in the art without making creative efforts based on the embodiment of the application belong to the scope of protection of the application.

In the application, unless otherwise specified and limited, the first feature “above” or “below” the second feature can include the first and second features in direct contact, or the first and second features are not in direct contact but are in contact through other features between them. Moreover, the first feature “on”, “above” and “on top of” the second feature includes the first feature being directly above and diagonally above the second feature, or simply indicating that the horizontal height of the first feature is higher than that of the second feature.

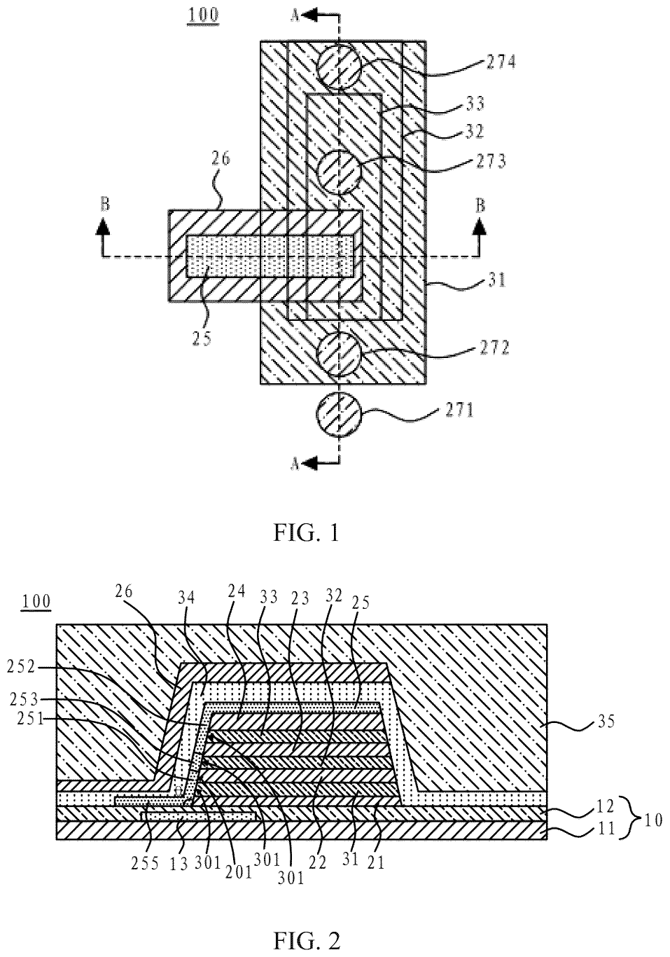

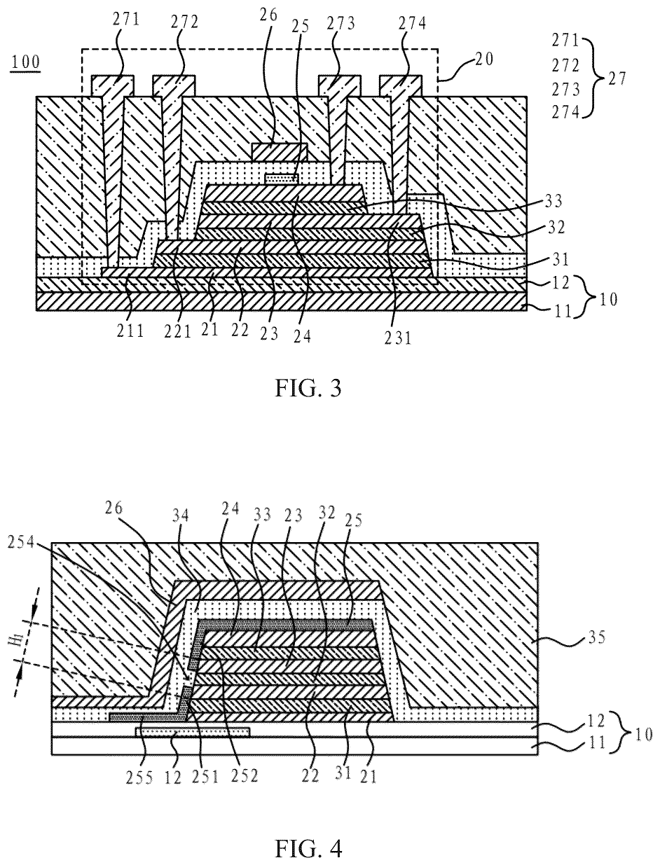

Refer to FIGS. 1 to 3, FIG. 1 is a structural plan view of the thin-film transistor provided by an embodiment of the display panel of the present invention, FIG. 2 is a cross-sectional view along the B-B direction of FIG. 1, and FIG. 3 is a cross-sectional view along the A-A direction of FIG. 1. The display panel 100 provided by the embodiment of the invention includes the substrate 10 and the thin-film transistor 20, which is disposed on the substrate 10. The thin-film transistor 20 can be applied to various circuits in the display panels, such as pixel driving circuits, gate driving circuits, source driving circuits, timing controllers, multiplexer circuits, etc.

Specifically, the display panel 100 includes the substrate 10, multiple ohmic contact layers (such as 21, 22, 23, 24), multiple insulating layers (such as 31, 32, 33), the semiconductor layer 25, the gate 26, and the source and drain layer 27. The multiple ohmic contact layers are stacked on the substrate 10, with at least one layer of insulating layers disposed between adjacent ohmic contact layers. The semiconductor layer 25 is disposed on at least the first sidewalls 201 of the multiple ohmic contact layers. The gate 26 is disposed on a side of the semiconductor layer 25 away from the substrate 10, and the source and drain layer 27 is disposed on a side of the gate 26 away from the substrate 10. The gate 26 and the semiconductor layer 25 are separated by the gate insulating layer 34, and the source and drain layer 27 and the gate 26 are separated by the interlayer dielectric layer 35. The semiconductor layer 25 includes multiple spaced active parts (such as 251, 252), and the active parts are in contact with the first sidewalls 201 of the two ohmic contact layers (such as 251 in contact with 21, 22, 252 in contact with 23, 24). The thin-film transistor 20 can be composed of but not limited to the structure formed by the aforementioned multiple ohmic contact layers, the semiconductor layer 25, the gate 26, and the source and drain layer 27.

In the existing thin-film transistors, the active layers are prepared on the same plane, and the multiple thin-film transistors are disposed in a planar configuration, resulting in a larger circuit footprint. Due to the limitations of exposure and etching processes, the channel length is generally above 2 micrometers, and the size of the transistors cannot be further reduced. The embodiment of the present invention forms the channel (the part between the active parts in contact with the two ohmic contact layers) on the first sidewalls 201 of the ohmic contact layers, and the channel length is determined by the distance between the two ohmic contact layers. Therefore, it is very easy to control the channel length of the embodiment of the invention to below 1 micrometer on the basis of the existing processes, forming the short-channel thin-film transistor device, achieving the purpose of reducing the size of the thin-film transistor, thereby increasing the on-state current. In addition, the embodiment of the present invention has the multiple ohmic contact layers stacked in the thickness direction of the display panel, which can realize the stacking of multiple thin-film transistors 20 in the thickness direction of the display panel, greatly reducing the footprint of the thin-film transistors 20, thereby improving the integration of the device.

Furthermore, to achieve electrical isolation between adjacent thin-film transistors 20, it is necessary to insulate the adjacent active parts of the semiconductor layer 25. In some embodiments, the thin-film transistor 20 is the polysilicon thin-film transistor, that is, the active parts of the semiconductor layer 25 are made of polysilicon material, and the semiconductor layer 25 also includes multiple oxidation insulating parts 253, each of which is located between two adjacent active parts (such as 251, 252), and the adjacent active parts are spaced apart by the oxidation insulating parts 253 to achieve electrical isolation.

Specifically, by forming an amorphous silicon film on the first sidewalls 201, the parts of the amorphous silicon film that need to be made insulated are each oxidized to form a silicon oxide (such as an oxide silicon film layer), thereby forming the oxidation insulating parts 253.

The oxidation insulating parts 253 and the active parts together form a continuous pattern, which can be achieved with only one film deposition process, without adding new film processes, making the process simple, and also enhancing the adhesion of the semiconductor layer 25 on the slope. The continuous pattern mentioned above refers to a pattern formed continuously without seam(s) or opening(s).

In other embodiments, as shown in FIG. 4, it is also possible to form the hollow part 254 between the adjacent active parts while etching the semiconductor layer 25, and no new process will be added. It is understood that the hollow part 254 penetrates the semiconductor layer 25 in its thickness direction, thereby achieving insulation between adjacent active parts. Compared with the embodiment shown in FIG. 2, the scheme of forming the hollow part 254 may have a risk of incomplete etching, and the adhesion of the film may be reduced. Therefore, the embodiment of the invention prefers the scheme of the oxidation insulating part(s), which results in stronger stability of the semiconductor film.

The semiconductor layer 25 covers at least the first sidewalls 201 of the multiple ohmic contact layers and the second sidewalls 301 of the multiple insulating layers on the same side as the first sidewalls 201. In the embodiment of the invention, the semiconductor layer 25 also includes the horizontal part 255, which is in contact with one of the active parts and is disposed on the surface of the substrate 10. This active part is the one closest to the substrate 10 among the multiple active parts, that is, this active part is the first active part 251. Since the active parts are inclined at a certain angle relative to the substrate 10, the horizontal part 255 is inclined with respect to the active parts. The material of the horizontal part 255 is amorphous silicon material. On the one hand, the corner where the horizontal part 255 and the first active part 251 meet can form seed crystals. The seed crystals can be generated along the direction of the slope where the first sidewalls 201 and the second sidewalls 301 are located. By controlling the thicknesses of the insulating layers and the ohmic contact layers, the channel length of the thin-film transistor 20 can be controlled between 0.01 to 1 micrometers, so that there is only one crystal grain in the channel, that is, the channel is composed of the single crystal grain, and there is no grain boundary. Compared with the existing thin-film transistors with multiple grain boundaries, the embodiments of the invention have the mobility of the thin-film transistors greatly improved while reducing the size of the thin-film transistors. On the other hand, by extending the semiconductor layer 25 to form the horizontal part 255, the adhesion between the semiconductor layer and the film layer(s) can be increased, improving the stability of the thin-film transistor device.

In some embodiments, the angle θ between the horizontal part 255 and the active parts is preferably 90° ˜135°, and this angle θ is also an angle between the first sidewalls 201 and the substrate 10 and an angle between the second sidewalls 301 and the substrate 10. The thickness between the two adjacent ohmic contact layers in the embodiment of the invention is 0.0071 to 1 micrometers, which can control the channel length to be below 1 micrometer.

In addition, the semiconductor layer 25 can also cover the surface of the multiple ohmic contact layers away from the substrate 10, that is, the semiconductor layer 25 can continue to extend upwards to form another horizontal part parallel to the substrate 10. In this way, the preparation of the small-sized semiconductor layer 25 can be achieved at a precision of the exposure machine of the existing process without changing the process.

The embodiment of the invention is illustrated by taking two stacked thin-film transistors as an example for explanation, but it is not limited to this, and it is also possible to stack three, four, or more thin-film transistors.

Specifically, as shown in FIGS. 1 to 3, the display panel includes the first ohmic contact layer 21, the first insulating layer 31, the second ohmic contact layer 22, the second insulating layer 32, the third ohmic contact layer 23, the third insulating layer 33, and the fourth ohmic contact layer 24, which are sequentially stacked on the substrate 10.

The semiconductor layer 25 includes the first active part 251 and the second active part 252, the first active part 251 is in contact with the first ohmic contact layer 21 and the second ohmic contact layer 22. And a part of the first active part 251 located between the first ohmic contact layer 21 and the second ohmic contact layer 22 forms the channel of one thin-film transistor, that is, the length of the channel can be determined by the length and inclination angle of the second sidewall 301 of the first insulating layer 31 between the first ohmic contact layer 21 and the second ohmic contact layer 22, and the channel length can be controlled to below 1 micrometer.

The source and drain layer 27 includes the first source 271 and the first drain 272, disposed on a side of the gate 26 away from the substrate 10, one of the first source 271 and the first drain 272 is electrically connected to the first ohmic contact layer 21, and the other is electrically connected to the second ohmic contact layer 22.

The second active part 252 is in contact with the third ohmic contact layer 23 and the fourth ohmic contact layer 24, and a part of the second active part 252 located between the third ohmic contact layer 23 and the fourth ohmic contact layer 24 forms the channel of another thin-film transistor. Similarly, the length of the channel is determined by the length and inclination angle of the second sidewall 301 of the third insulating layer 33 between the third ohmic contact layer 23 and the fourth ohmic contact layer 24, and the channel length can be controlled to below 1 micrometer.

The source and drain layer 27 also includes the second source 273 and the second drain 274 disposed on a side of the gate 26 away from the substrate 10, one of the second source 273 and the second drain 274 is electrically connected to the third ohmic contact layer 23, and the other is electrically connected to the fourth ohmic contact layer 24.

In the embodiment of the invention, as shown in FIG. 1, the orthographic projection of the gate 26 on the substrate 10 covers the orthographic projection of the semiconductor layer 25 on the substrate 10, which facilitates the control of the formation positions and the lengths of the channels of the multiple thin-film transistors.

In the aforementioned embodiment, one thin-film transistor is composed of but not limited to the first active part 251, the first ohmic contact layer 21, the second ohmic contact layer 22, the first source 271, the first drain 272, and the gate 26. And the other thin-film transistor is composed of but not limited to the second active part 252, the third ohmic contact layer 23, the fourth ohmic contact layer 24, the second source 273, the second drain 274, and the gate 26, which not only allows the preparation of short-channel thin-film transistor devices on the basis of existing processes, increasing the on-state current, but also realizes the stacking of multiple thin-film transistors in the thickness direction, reducing the footprint of the transistors, and improving the integration of the device, which is conducive to the integration of IC circuits on the substrate.

As shown in FIGS. 1 and 3, the first source 271 and the first drain 272 are disposed on one side of the gate 26, and the second source 273 and the second drain 274 are disposed on the opposite side of the gate 26. In other words, the orthographic projection of the first source 271 and the first drain 272 on the substrate 10 is located on one side of the orthographic projection of the gate 26 on the substrate 10, and the second source 273 and the second drain 274 are located on the opposite side of the orthographic projection of the gate 26 on the substrate 10. This facilitates the via connections between the sources and the drains of the two thin-film transistors with their corresponding ohmic contact layers.

Specifically, as shown in FIG. 3, the first ohmic contact layer 21 includes the first protrusion 211, the orthographic projection of the first protrusion 211 on the substrate 10 does not overlap with the orthographic projections of the second, third, and fourth ohmic contact layers 22, 23, and 24 on the substrate 10, and the first protrusion 211 is electrically connected to one of the first source 271 and the first drain 272. By arranging the first ohmic contact layer 21 protruding above the upper ohmic contact layer, it is possible to avoid the first source 271/first drain 272 from passing through the upper ohmic contact layer and avoid contact with the upper ohmic contact layer.

Similarly, the second ohmic contact layer 22 includes the second protrusion 221, the orthographic projection of the second protrusion 221 on the substrate 10 does not overlap with the orthographic projections of the third and fourth ohmic contact layers 23 and 24 on the substrate 10, and the second protrusion 221 is electrically connected to the other of the first source 271 and the first drain 272. The second protrusion 221 and the first protrusion 211 are on the same side of the gate 26.

The third ohmic contact layer 23 includes the third protrusion 231, the orthographic projection of the third protrusion 231 on the substrate 10 does not overlap with the orthographic projection of the fourth ohmic contact layer 24 on the substrate 10, and the third protrusion 231 is electrically connected to one of the second source 273 and the second drain 274. The third protrusion 231 is disposed on a side different from the second protrusion 221 and the first protrusion 211, and the third protrusion 231 is on the opposite side of the gate 26.

In other embodiments, the first source 271, the first drain 272, the second source 273, and the second drain 274 can also be on the same side of the gate 26, but considering the wiring space, it is preferred to set the first source 271, the first drain 272, and the second source 273, and the second drain 274 on opposite sides of the gate 26.

The aforementioned embodiment is the stack of two thin-film transistors, and other embodiments with more stacked thin-film transistors are similar to the aforementioned embodiment and reference may be made to the above description.

Furthermore, to achieve the series connection of thin-film transistors, the ohmic contact layers of two thin-film transistors can be electrically connected through vias.

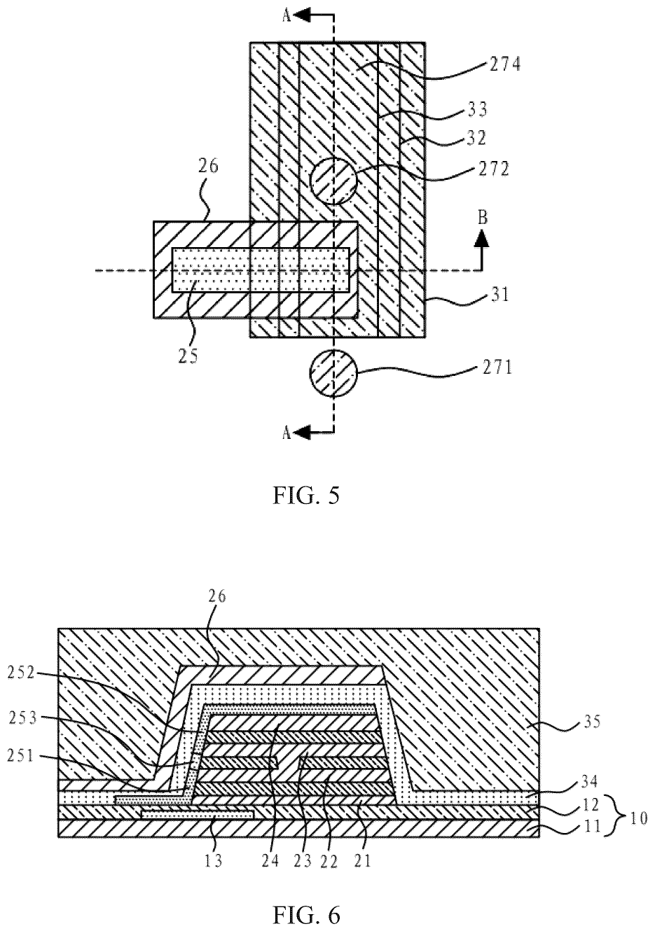

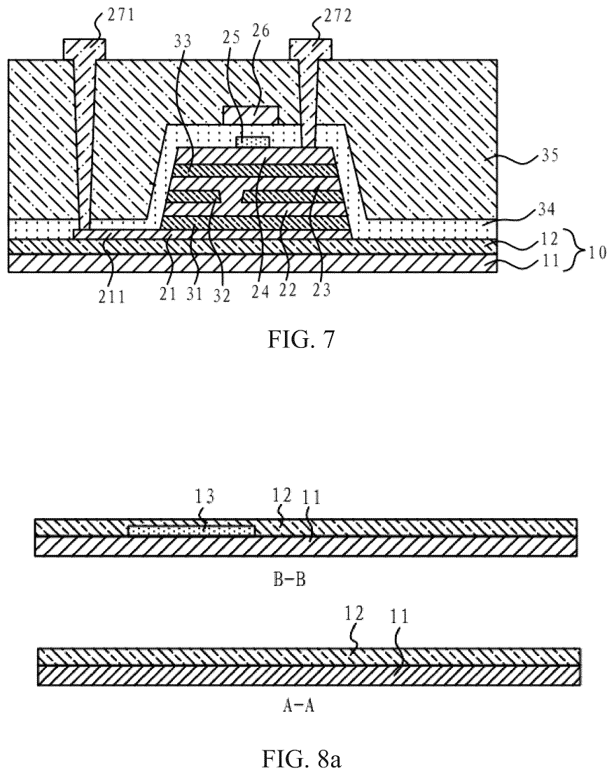

Specifically, refer to FIGS. 5 to 7, FIG. 5 is a top view of the thin-film transistor of another embodiment of the invention, FIG. 6 is a cross-sectional view along the B-B direction of FIG. 5, and FIG. 7 is a cross-sectional view along the A-A direction of FIG. 6. In the embodiment shown in FIGS. 5 to 7, still taking two thin-film transistors as an example for explanation, and reference can be made to the description of this embodiment for the structure of more thin-film transistors. To achieve the series connection of two thin-film transistors, the third ohmic contact layer 23 can be electrically connected to the second ohmic contact layer 22. The second insulating layer 32 includes the via, and the third ohmic contact layer 23 is electrically connected to the second ohmic contact layer 22 through the via. In this embodiment, the two thin-film transistors in series only need one source and one drain, that is, the source and drain layer 27 includes the first source 271 and the first drain 272, diposed on a side of the gate 26 away from the substrate 10, one of which is electrically connected to the first ohmic contact layer 21, and the other is electrically connected to the fourth ohmic contact layer 24.

The first source 271 and the first drain 272 are respectively diposed on two opposite sides of the gate 26 to facilitate wiring design. That is, the orthographic projection of the first source 271 on the substrate 10 is located on one side of the orthographic projection of the gate 26 on the substrate 10, and the orthographic projection of the first drain 272 on the substrate 10 is located on the other side of the orthographic projection of the gate 26 on the substrate 10.

Furthermore, the first ohmic contact layer 21 includes the first protrusion 211, the orthographic projection of the first protrusion 211 on the substrate 10 does not overlap with the orthographic projections of the second, third, and fourth ohmic contact layers 22, 23, and 24 on the substrate 10, and the first protrusion 211 is electrically connected to one of the first source 271 and the first drain 272. By extending the first ohmic contact layer 21 to form the protrusion 211 that protrudes above the upper ohmic contact layers (22, 23, 24), the subsequently formed first source 271/first drain 272 can bypass the upper ohmic contact layers and directly pass through the vias in the insulating layer to be electrically connected to the first ohmic contact layer 21.

In the aforementioned embodiment of the invention, the spacing between two adjacent active parts is greater than zero and less than H1, where H1 is the sum of the widths of the first sidewalls 201 of the two adjacent ohmic contact layers connected to the two active parts and the width(s) of the second sidewall(s) 301 of the insulating layer between the two adjacent ohmic contact layers. For example, as shown in FIG. 4, the spacing between the first active part 251 and the second active part 252 is greater than zero and less than H1, where H1 is the sum of the width of the first sidewall 201 of the second ohmic contact layer 22, the width of the second sidewall 301 of the second insulating layer 32, and the width of the first sidewall 201 of the third ohmic contact layer 23. That is, H1 corresponds to the width of the hollow part 254 or the maximum width of the oxidation insulating part 253, which can ensure both the electrical insulation between adjacent active parts and the contact connection of the active parts with the underlying ohmic contact layers.

In some embodiments, the substrate 10 includes the base substrate 11 and the buffer layer 12 disposed between the thin-film transistor 20 and the base substrate 11. As shown in FIGS. 2 and 6, to avoid the impact of environmental light exposure on the electrical properties of the semiconductor layer 25, the light-shielding layer 13 can be disposed between the buffer layer 12 and the base substrate 11, and the orthographic projection of the light-shielding layer 13 on the base substrate 11 covers the orthographic projections of the various active parts of the semiconductor layer 25 on the base substrate 11.

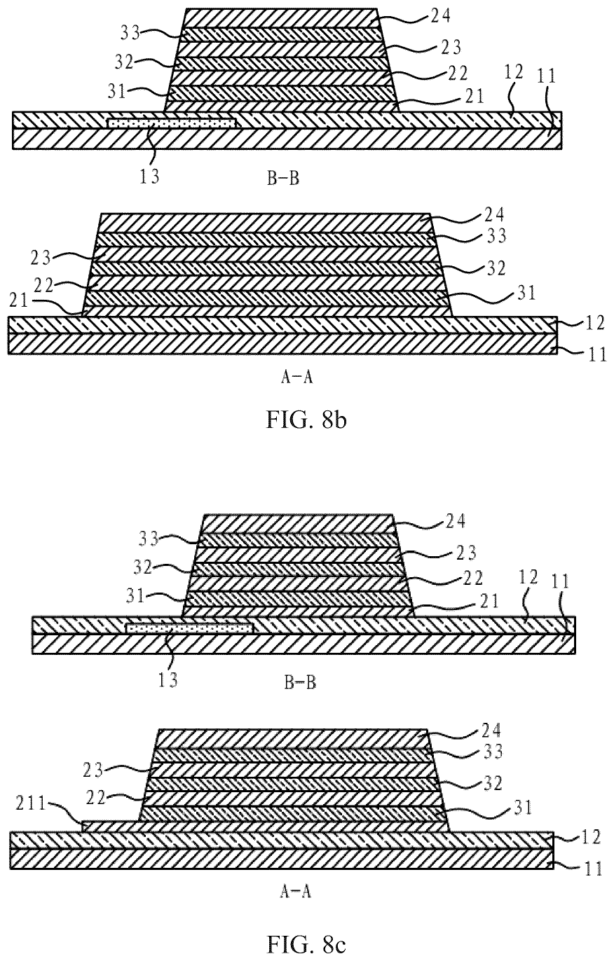

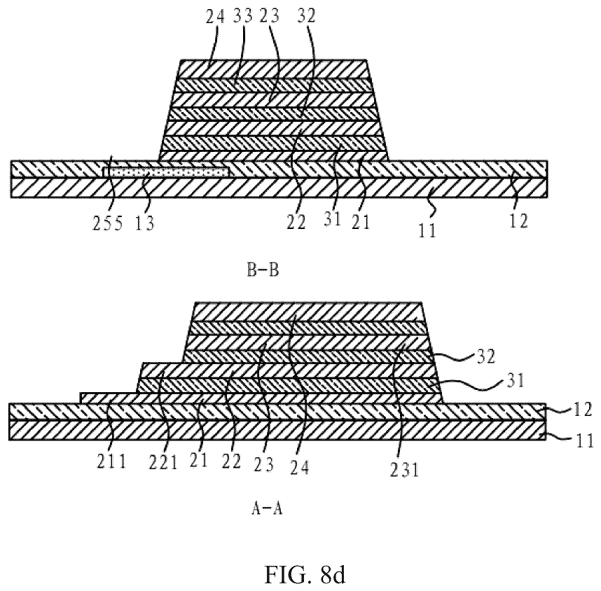

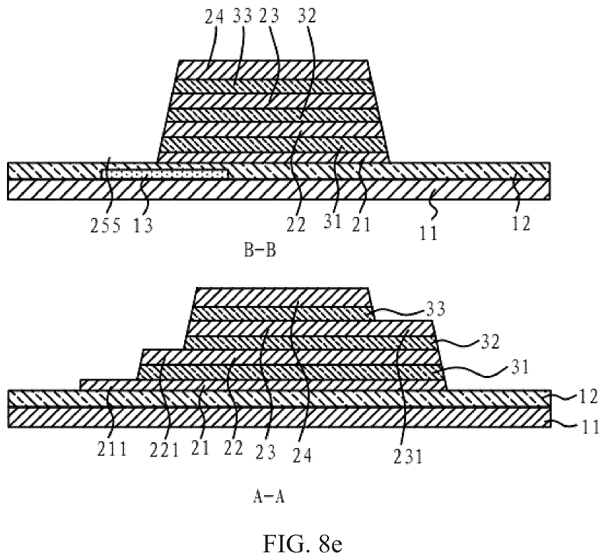

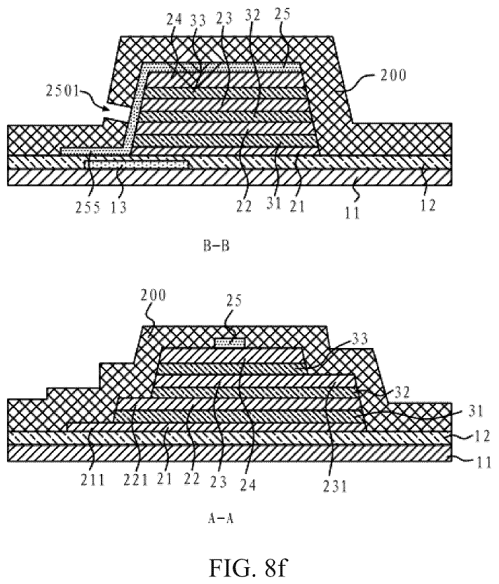

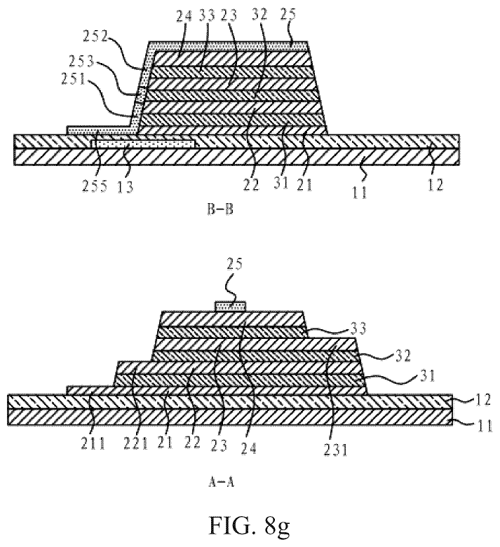

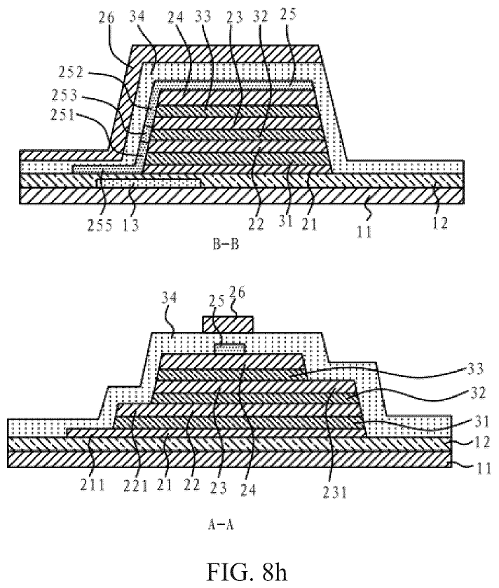

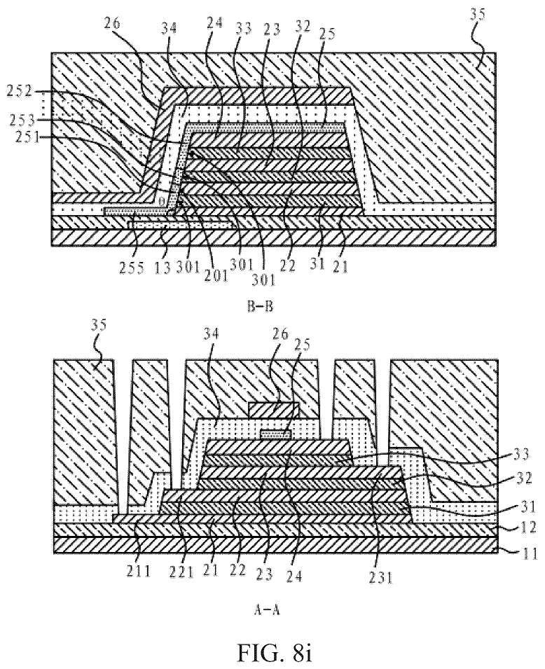

The process of aforementioned display panel preparation method is shown in FIGS. 8a to 8i, and the preparation method includes: S10, depositing materials of multiple ohmic contact layers and multiple insulating layers in alternation on the substrate 10, as shown in FIGS. 8a and 8b; S20, etching different positions of the multiple ohmic contact layers and the multiple insulating layers to different depths to form ohmic contact layers of different lengths and multiple insulating layers of different lengths, as shown in FIGS. 8c to 8e; S30, depositing amorphous silicon material on the outermost ohmic contact layer, and oxidizing the amorphous silicon in the set area 2501 to form an oxide silicon compound, as shown in FIGS. 8f and 8g; S40, sequentially preparing the gate 26 and the source and drain layer 27, as shown in FIGS. 8h and 8i.

Specifically, in S10, the light-shielding layer 13 is formed on the base substrate 11, and the material of the light-shielding layer 13 includes but is not limited to metal materials. Then, the buffer layer 12 is deposited on the light-shielding layer 13.

The material of the buffer layer 12 includes but is not limited to any one or the combination of silicon nitride, silicon oxide, or silicon oxynitride.

In S20, as shown in FIGS. 8c to 8e, taking two thin-film transistors as an example, materials of the first ohmic contact layer 21, the first insulating layer 31, the second ohmic contact layer 22, the second insulating layer 32, the third ohmic contact layer 23, the third insulating layer 33, and the fourth ohmic contact layer 24 are sequentially stacked on the buffer layer 12; then etched to different depths to form the first protrusion 211, the second protrusion 221, and the third protrusion 231. The different depth etching process can be carried out through the same grayscale mask, or it can be carried out multiple times through different photomasks, and this is not limited.

The aforementioned ohmic contact layers are all N-type heavily doped amorphous silicon materials, and the ohmic contact layers can also be doped with impurity elements such as phosphorus or arsenic. The material of the aforementioned insulating layers can be silicon nitride, silicon oxide, or silicon oxynitride, and other commonly used inorganic insulating materials.

In S30, referring to FIGS. 8f and 8h, amorphous silicon material is deposited on the fourth ohmic contact layer 24, and the amorphous silicon is subjected to crystallization treatment, and then the amorphous silicon material is etched to form the pattern of the semiconductor layer 25. Then the hard mask layer 200 is formed on the semiconductor layer 25, and the notch is formed in the set area 2501 to expose the amorphous silicon material inside the set area 2501, and the hard mask layer 200 can be the SiN layer. Then the device is placed in an oxygen environment, causing the exposed amorphous silicon material to be oxidized into an oxide silicon compound, becoming an insulator, that is, forming an oxidation insulating part 253. Finally, the hard mask layer is removed.

Excimer laser annealing process can be used to crystallize the amorphous silicon material, allowing the amorphous silicon to be transformed into the polycrystalline silicon structure, and then the polycrystalline silicon structure is etched to form the pattern of the semiconductor layer 25. Since the energy of the excimer laser annealing process is limited and all absorbed by the amorphous silicon, the ohmic contact layer can still maintain an amorphous silicon structure during the crystallization treatment of the amorphous silicon layer. The crystallization treatment of amorphous silicon can also be carried out after the oxidation treatment, and this is not limited.

In S40, the gate insulating layer 34 is first formed on the semiconductor layer 25, and then the pattern of the gate 26 is formed. Then the material of the interlayer dielectric layer 35 is deposited on the gate 26, and the interlayer dielectric layer 35 and the gate insulating layer 34 are etched through the same etching process to form vias of different depths at different positions. Then the pattern of the source and drain layer 27 is formed on the interlayer dielectric layer 35, and the sources and the drains of the source and drain layer 27 are electrically connected to the corresponding ohmic contact layers through vias of different depths at different positions.

In summary, the embodiment of the invention provides the display panel, including the substrate 10, multiple ohmic contact layers, multiple insulating layers, the semiconductor layer 25, the gate 26, and the source and drain layer 27, where at least one layer of the insulating layers is disposed between adjacent ohmic contact layers. The semiconductor layer 25 is disposed on at least the first sidewalls of the multiple ohmic contact layers. The semiconductor layer 25 includes multiple spaced active parts that are in contact with the first sidewalls 201 of the two ohmic contact layers, the gate 26 is disposed on a side of the semiconductor layer 25 away from the substrate 10, and the source and drain layer 27 is disposed on a side of the gate 26 away from the substrate 10, and is electrically connected to the corresponding ohmic contact layer. By stacking multiple ohmic contact layers and setting the semiconductor layer 25 on the sidewalls of the ohmic contact layers, not only the length of the thin-film transistor is reduced, and the on-state current is increased, but also the multiple thin-film transistors are stacked in the thickness direction of the display panel, reducing the volume of the thin-film transistors, reducing the footprint of the thin-film transistors, and is conducive to improving the integration of the device.

In the aforementioned embodiments, the description of each embodiment focuses on different aspects, and for the parts that are not detailed in the certain embodiment, refer to the relevant descriptions in other embodiments.

The above has provided the detailed introduction to the display panel provided by an embodiment of the invention. This article uses specific examples to elaborate on the principles and implementation methods of the invention. The description of the above embodiments is only for the purpose of helping to understand the technical solutions and core ideas of the invention; ordinary technicians in the field should understand that they can still modify the technical solutions recorded in the aforementioned embodiments, or equivalently replace some technical features; and these modifications or replacements do not deviate from the essence of the technical solutions of the embodiments of the invention.

1. A display panel, comprising:
a substrate;
multiple ohmic contact layers, stacked on the substrate;
multiple insulating layers, with at least one insulating layer of the insulating layers between two adjacent ones of the ohmic contact layers;
a semiconductor layer, disposed on at least first sidewalls of the ohmic contact layers that are on one same side, wherein the semiconductor layer includes multiple spaced active parts each in contact and connected with the first sidewalls of two of the ohmic contact layers;
a gate, disposed on a side of the semiconductor layer away from the substrate; and
a source and drain layer, disposed on a side of the gate away from the substrate, and the source and drain layer being electrically connected to a corresponding one of the ohmic contact layers.

2. The display panel of claim 1, wherein the semiconductor layer comprises multiple oxidation insulating parts, each oxidation insulating part is located between two adjacent ones of the active parts.

3. The display panel of claim 2, wherein the active parts and the oxidation insulating parts form a continuous pattern.

4. The display panel of claim 3, wherein an orthographic projection of the oxidation insulating part on the first sidewalls of the ohmic contact layers is located between the two adjacent ohmic contact layers.

5. The display panel of claim 2, wherein a material of the oxidation insulating parts comprises silicon oxide, and a material of the active parts comprises polycrystalline silicon.

6. The display panel of claim 1, wherein the semiconductor layer comprises a hollow part, which is located between two adjacent ones of the active parts.

7. The display panel of claim 1, wherein the display panel comprises a first ohmic contact layer, a first insulating layer, a second ohmic contact layer, a second insulating layer, a third ohmic contact layer, a third insulating layer, and a fourth ohmic contact layer, sequentially stacked on the substrate, which constitute the multiple ohmic contact layers and the multiple insulating layer.

8. The display panel of claim 7, wherein the semiconductor layer comprises a first active part and a second active part which constitute the multiple active parts, the first active part is in contact with the first ohmic contact layer and the second ohmic contact layer, and the second active part is in contact with the third ohmic contact layer and the fourth ohmic contact layer.

9. The display panel of claim 8, wherein the source and drain layer comprises a first source, a first drain, a second source, and a second drain, disposed on a side of the gate away from the substrate, one of the first source and the first drain is electrically connected to the first ohmic contact layer, the other of the first source and the first drain is electrically connected to the second ohmic contact layer, one of the second source and the second drain is electrically connected to the third ohmic contact layer, and the other of the second source and the second drain is electrically connected to the fourth ohmic contact layer.

10. The display panel of claim 9, wherein orthographic projections of the first source and the first drain on the substrate are located on a side of an orthographic projection of the gate on the substrate, and orthographic projections of the second source and the second drain are located on an opposite side of the orthographic projection of the gate on the substrate.

11. The display panel of claim 9, wherein
the first ohmic contact layer comprises a first protrusion, an orthographic projection of the first protrusion on the substrate does not overlap with orthographic projections of the second, third, and fourth ohmic contact layers on the substrate, and the first protrusion is electrically connected to one of the first source and the first drain;
the second ohmic contact layer comprises a second protrusion, an orthographic projection of the second protrusion on the substrate does not overlap with the orthographic projections of the third and fourth ohmic contact layers on the substrate, and the second protrusion is electrically connected to the other of the first source and the first drain;
the third ohmic contact layer comprises a third protrusion, an orthographic projection of the third protrusion on the substrate does not overlap with the orthographic projection of the fourth ohmic contact layer on the substrate, and the third protrusion is electrically connected to one of the second source and the second drain.

12. The display panel of claim 8, wherein the second insulating layer comprises a via, and the third ohmic contact layer is electrically connected to the second ohmic contact layer through the via.

13. The display panel of claim 12, wherein the source and drain layer comprises a first source and a first drain disposed on a side of the gate away from the substrate, one of the first source and the first drain is electrically connected to the first ohmic contact layer, and the other of the first source and the first drain is electrically connected to the fourth ohmic contact layer.

14. The display panel of claim 13, wherein an orthographic projection of the first source on the substrate is located on a side of an orthographic projection of the gate on the substrate, and an orthographic projection of the first drain on the substrate is located on the other side of the orthographic projection of the gate on the substrate.

15. The display panel of claim 13, wherein the first ohmic contact layer comprises a first protrusion, an orthographic projection of the first protrusion on the substrate does not overlap with orthographic projections of the second, third, and fourth ohmic contact layers on the substrate, and the first protrusion is electrically connected to one of the first source and the first drain.

16. The display panel of claim 8, wherein a spacing between the first active part and the second active part is greater than zero and less than H1, where H1 is a sum of widths of the first sidewall of the second ohmic contact layer and a second sidewall of the second insulating layer and the first sidewall of the third ohmic contact layer.

17. The display panel of claim 1, wherein the semiconductor layer further comprises a horizontal part, which is in contact and connected with one of the active parts and is disposed on a surface of the substrate.

18. The display panel of claim 17, wherein the horizontal part is inclined with respect to the active part, and an angle between the horizontal part and the active part is 90°˜135°.

19. The display panel of claim 17, wherein a material of the horizontal part comprises amorphous silicon material.

20. The display panel of claim 1, wherein the substrate comprises a base substrate, a buffer layer disposed on a side of the base substrate close to the ohmic contact layers, and a light-shielding layer located between the base substrate and the buffer layer, an orthographic projection of the light-shielding layer on the base substrate covers orthographic projections of the various active parts of the semiconductor layer on the base substrate.
